(19) United States
(12) Patent Application Publication
(10) Pub. No.: US 2013/0062648 A1
(43) Pub. Date: Mar. 14, 2013

(54) LIGHT-EMITTING DEVICE AND LIGHT-EMITTING DEVICE MANUFACTURING METHOD

(71) Applicant: Yoshiro NISHIMURA, Okaya-shi (JP)

(72) Inventor: Yoshiro NISHIMURA, Okaya-shi (JP)

(73) Assignee: OLYMPUS CORPORATION, Tokyo (JP)

(21) Appl. No.: 13/608,412

(22) Filed: Sep. 10, 2012

(30) Foreign Application Priority Data
Sep. 12, 2011 (JP) 2011-198717

(51) Int. Cl. H01L 33/44

(52) U.S. Cl. 257/98; 438/29; 257/E33.061

(57) ABSTRACT

A light-emitting device includes: a light-emitting element that generates ultraviolet light; a first wavelength conversion layer placed on the light-emitting element, the first wavelength conversion layer including a plurality of types of phosphor particles dispersed in a transparent resin, each of the plurality of types of phosphor particles converting the ultraviolet light into light having a longer wavelength; and a second wavelength conversion layer placed on at least a part of the first wavelength conversion layer, the second wavelength conversion layer including at least any of the plurality types of phosphor particles dispersed in a transparent resin.

### CROSS REFERENCE TO RELATED APPLICATION

This application claims the benefit of Japanese Application No. 2011-198717 filed in Japan on Sep. 12, 2011 the contents of which are incorporated herein by this reference.

### BACKGROUND OF THE INVENTION

1. Field of the Invention

Embodiments of the present invention relate to a light-emitting device including a light-emitting element and phosphor layers and a method for manufacturing the light-emitting device.

2. Description of the Related Art

Light-emitting devices using a semiconductor light-emitting element have a small size and good power efficiency. Accordingly, light-emitting devices including a semiconductor light-emitting element such a light-emitting diode (LED) or a laser diode (hereinafter referred to as “LD”) are used for various types of light sources. Here, light generated by a semiconductor light-emitting element has a steep spectral distribution. Thus, in a light-emitting device that generates white color light, it is necessary to convert the wavelengths of light generated by the semiconductor light-emitting element.

In order to generate white color light, there is a light-emitting device including a combination of an ultraviolet light-emitting diode and three types of phosphors that emit light in blue, green and red.

For example, Japanese Patent Application Laid-Open Publication No. 2010-50438 discloses a light-emitting device including an ultraviolet light-emitting element mounted on a substrate and a phosphor layer placed on the ultraviolet light-emitting element, the phosphor layer including a mixture of three types of, i.e., blue, yellow and red, phosphors and a transparent resin.

### SUMMARY OF THE INVENTION

A light-emitting device according to an embodiment of the present invention includes: a light-emitting element that generates ultraviolet light; a first wavelength conversion layer placed on the light-emitting element, the first wavelength conversion layer including a plurality of types of phosphor particles dispersed in a transparent resin, each of the plurality of types of phosphor particles converting the ultraviolet light into light having a longer wavelength; and a second wavelength conversion layer placed on at least a part of the first wavelength conversion layer, the second wavelength conversion layer including at least any of the plurality types of phosphor particles dispersed in the transparent resin.

A light-emitting device manufacturing method according to another embodiment of the present invention includes the steps of: forming a first wavelength conversion layer on a light-emitting element that generates ultraviolet light, the first wavelength conversion layer including a plurality of types of phosphor particles dispersed in a transparent resin, each of the plurality of types of phosphor particles converting the ultraviolet light to light having a longer wavelength; measuring light generated by the first wavelength conversion layer; and depositing, based on a result of the measurement, a second wavelength conversion layer on at least part of the first wavelength conversion layer, the second wavelength conversion layer including at least any of the plurality of types of phosphor particles dispersed in the transparent resin, to correct light generated by the first wavelength conversion layer to light meeting a predetermined specification.

### BRIEF DESCRIPTION OF THE DRAWINGS

FIG. 1 is a perspective view of a light-emitting device according to a first embodiment;

FIG. 2 is a cross-sectional diagram illustrating a structure of the light-emitting device according to the first embodiment;

FIG. 3 is a flowchart illustrating a method for manufacturing a light-emitting device according to the first embodiment;

FIG. 4 is a perspective view of a light-emitting device according to the first embodiment;

FIG. 5 is a cross-sectional diagram illustrating a structure of the light-emitting device according to the first embodiment;

FIG. 6 is a cross-sectional diagram illustrating a structure of a light-emitting device according to a second embodiment; and

FIG. 7 is a cross-sectional diagram illustrating a structure of a light-emitting device according to a third embodiment.

### DETAILED DESCRIPTION OF THE PREFERRED EMBODIMENTS

### First Embodiment

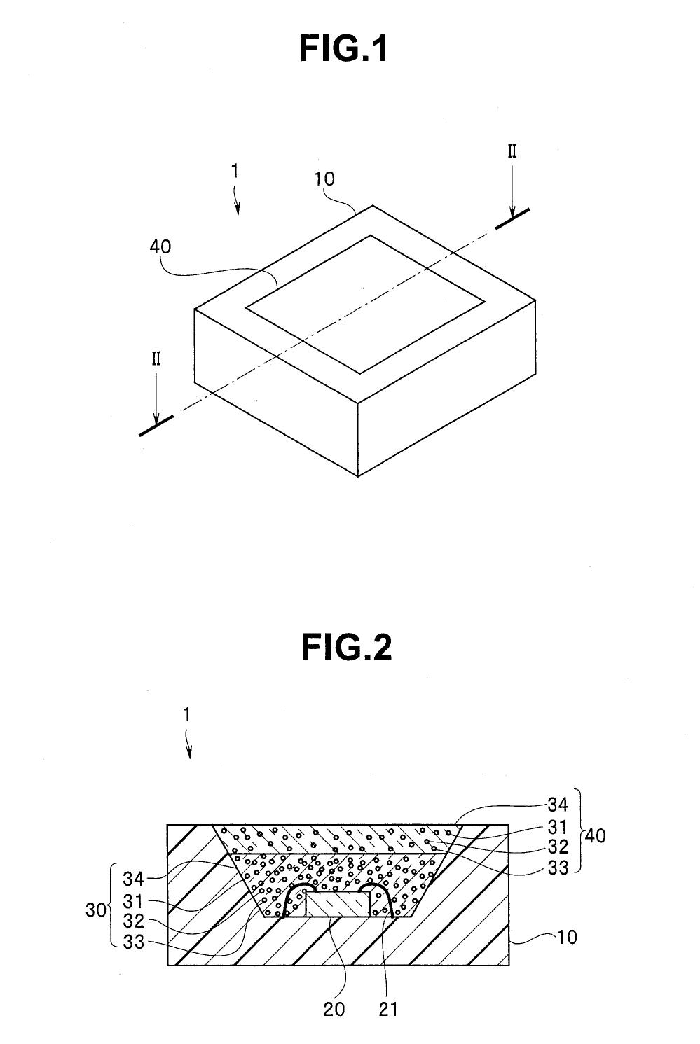

FIG. 1 is a perspective view of a light-emitting device 1 according to a first embodiment, and FIG. 2 is a cross-sectional diagram illustrating a structure of the light-emitting device 1. Here, each of the drawings herein is a schematic diagram for illustration and has, e.g., an aspect ratio different from that of an actual one.

As illustrated in FIGS. 1 and 2, the light-emitting device 1 includes a light-emitting element 20, a first wavelength conversion layer 30, a second wavelength conversion layer 40 and a package 10 that includes an opaque material.

The package 10 includes, e.g., metal, resin or ceramic such as ceramic, glass, aluminum nitride, aluminum, copper, glass fiber-contained epoxy resin or polyimide. In a substantial center portion of the package 10, a recess portion including four side walls (side surfaces) and a bottom portion is formed. An opening of the recess portion may have, e.g., a polygonal shape or a circular shape according to the shape of the light-emitting element 20. At the bottom portion of the recess portion, the package 10 includes electrode pads (not illustrated) for electrical connection with the light-emitting element 20, and through wirings (not illustrated), which are lead wiring portions extending from the electrode pads to an outer surface (bottom surface) of the package 10.

The light-emitting element 20 is selected from light-emitting elements that generate light containing at least ultraviolet light (for example, light with wavelengths of 380 to 430 nm), such as organic EL elements, inorganic EL elements and laser diode elements. From the perspective of light generation efficiency, an LED element is preferable, and an ultraviolet light-emitting diode element formed on a sapphire substrate, the ultraviolet light-emitting diode element including a gallium nitride-based compound semiconductor, is particularly preferable. Electrode portions of the light-emitting element 20 are connected to the electrode pads of the package 10 via bonding wires 21 each including a thin metal wire of, e.g., gold (Au), aluminum (Al) or copper (Cu).

The first wavelength conversion layer 30 covering the light-emitting element 20 includes a transparent resin 34 including first phosphor particles 31, second phosphor particles 32 and third phosphor particles 33 dispersed therein, and converts light generated by the light-emitting element 20 to light having longer wavelengths. The transparent resin 34 includes, e.g., an epoxy-based resin, a silicone-based resin or an acrylic-based resin, which is thermally cured or cured by ultraviolet irradiation. The first wavelength conversion layer 30 may be subjected to curing processing after charging of the first wavelength conversion layer 30 in an uncured state, which has fluidity, into the recess portion, or may be subjected to curing processing in advance and bonded as a resin sheet. Also, it is possible that the light-emitting element 20 is sealed with a transparent resin and the first wavelength conversion layer 30 is placed thereon.

The first phosphor particles 31 convert ultraviolet light having wavelengths of no more than 430 nm to blue light with wavelengths of 435 nm to 480 nm. The second phosphor particles 32 convert ultraviolet light to green light with wavelengths of 500 nm to 550 nm. The third phosphor particles 33 convert ultraviolet light to red light with wavelengths of 580 nm to 650 nm.

The respective phosphor particles 31 to 33 are arbitrarily selected from various types of known phosphor materials, for example, YAG-based, TAG-based, SiAlON-based, CaAlSiN₃-based, alkaline earth orthosilicate-based and lanthanum oxynitride-based phosphor materials.

The second wavelength conversion layer 40 has a configuration similar to that of the first wavelength conversion layer 30, but contains an amount of phosphors that is smaller than that of the first wavelength conversion layer 30. For example, as described later, the first wavelength conversion layer 30 has a phosphor particle content of 23 wt % while the second wavelength conversion layer 40 has a phosphor particle content of 11.5 wt %. Here, a phosphor particle content can be obtained by (total weight of phosphors/(total weight of phosphors+weight of transparent resin)×100). The second wavelength conversion layer 40 has such a low phosphor particle content because, as described later, the second wavelength conversion layer 40 is a correction layer that corrects light generated by the first wavelength conversion layer 30 to light meeting predetermined specifications.

The second wavelength conversion layer 40 only needs to contain a plurality of types of phosphor particles that convert ultraviolet light to white color light, and may contain, for example, two types of phosphor particles, i.e., phosphor particles that convert ultraviolet light to yellow light and phosphor particles that convert ultraviolet light to red light.

In other words, white color light generated by the light-emitting device 1 may be pseudo white color light as long as such pseudo white color light can be recognized as having a white color natural to human eyes and has, e.g., a spectral distribution that differs depending on the specifications of the light-emitting device 1.

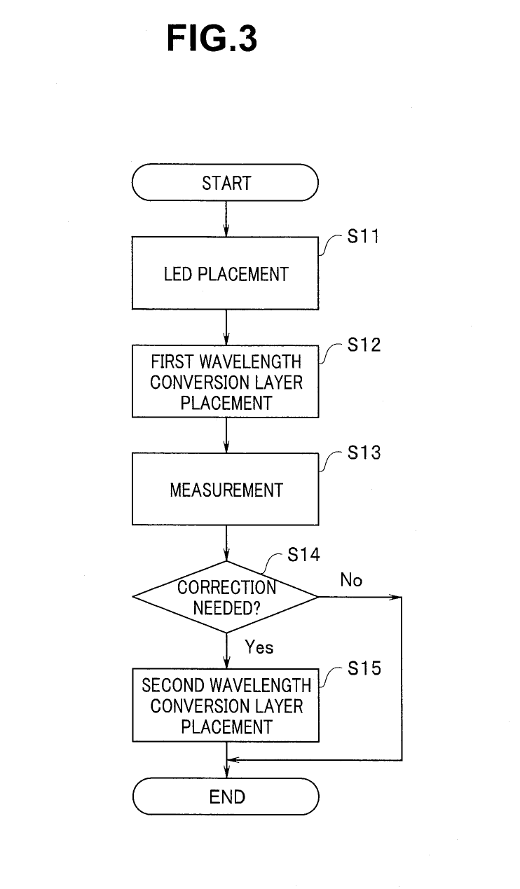

Next, a method for manufacturing the light-emitting device 1 will be described with reference to FIG. 3.

### <Step S11>

A light-emitting element 20 is die-bonded to a bottom portion of a recess portion of a package 10 using, e.g., a transparent resin adhesive, a white resin adhesive, a silver (Ag) paste or eutectic solder. Then, electrode portions of the light-emitting element 20 are connected to electrode pads of the package 10 via wire bonding.

For the connection between the light-emitting element 20 and the electrode pads of the package 10, a flip-chip method or a TAB (tape automated bonding) method may be employed.

### <Step S12>

A first wavelength conversion layer 30 including a transparent resin 34 that includes first phosphor particles 31, second phosphor particles 32 and third phosphor particles 33 dispersed therein is charged into the recess portion so as to cover the light-emitting element 20. Here, a composition of the first wavelength conversion layer 30 is designed in advance so as to generate light with intensity and color meeting predetermined specifications. In other words, an amount of phosphor particles contained in the first wavelength conversion layer 30 and proportions of contents of three types of phosphor particles in the first wavelength conversion layer 30 are determined. For example, the content of the first phosphor particles 31 is 18 wt %, the content of the second phosphor particles is 4 wt %, the content of the third phosphor particles is 1 wt % and the content of the transparent resin is 77 wt %.

### <Step S13>

Predetermined electric power is applied to the electrode pads of the package 10, whereby the light-emitting element 20 emits light. Then, the three types of phosphor particles 31 to 33 in the first wavelength conversion layer 30 each convert the ultraviolet light emitted by the light-emitting element 20 to light with longer wavelengths, whereby three wave-mixed white color light is generated from the first wavelength conversion layer 30.

As already described, the composition of the first wavelength conversion layer 30 is designed in advance so as to generate light having intensity and color meeting predetermined specifications. However, there may be a case where light meeting the predetermined specifications is not generated because of, e.g., in-process variations. Thus, in the method for manufacturing the light-emitting device 1, the light generated by the first wavelength conversion layer 30 is measured in the middle of the manufacture.

Although the content of the measurement is arbitrarily determined according to the specifications of the light-emitting device 1, the content of the measurement includes, for example, light emission intensity and spectral distribution, and the in-plane distribution is also preferably measured.

### <Step S14>

If it is determined as a result of the measurement that light meeting the predetermined specifications is generated (Yes), the manufacture of the light-emitting device 1 is completed. Here, a protection layer that includes a transparent resin only may further be formed so as to cover the first wavelength conversion layer 30. Also, an optical component such as a lens or a prism may be placed.

Meanwhile, if it is determined as a result of the measurement that light meeting the predetermined specifications is not generated (No), a second wavelength conversion layer 40 is placed in step S15.

### <Step S15>

A composition, etc., of the second wavelength conversion layer 40 are determined according to the result of the measurement. Here, since the second wavelength conversion layer 40 is a correction layer, a phosphor particle content therein is smaller than the phosphor particle content in the first wavelength conversion layer 30. This is because the light generated by the phosphor particles in the first wavelength conversion layer 30 is prevented from being excessively absorbed by the phosphor particles in the second wavelength conversion layer 40.

The phosphor particle content in the second wavelength conversion layer 40 is preferably no more than 75% and more preferably no more than 50% of the phosphor particle content in the first wavelength conversion layer 30, and a lower limit of the phosphor particle content in the second wavelength conversion layer 40 is not specifically limited and is, for example, 1%. In other words, where the phosphor particle content in the first wavelength conversion layer 30 is 23 wt %, the phosphor particle content in the second wavelength conversion layer 40 is preferably no more than 17.25 wt % and more preferably no more than 11.5 wt %, and has a lower limit of 0.23 wt %. Within the aforementioned range, a predetermined correction effect can be obtained.

For example, if the amount of light is simply insufficient, the second wavelength conversion layer 30 having proportions of contents of phosphor particles that are the same as those of the first wavelength conversion layer 30 is used. Here, the proportions of contents are proportions of the three types of phosphor particles, and for examples, where the content of the first phosphor particle 31 is 18 wt %, the content of the second phosphor particle is 4 wt % and the content of the third phosphor particle is 1 wt %, a proportion of the content of the first phosphor particle 31 is 78.3 wt % (18/(18+4+1)×100).

Also, for example, if the blue light is weak, a second wavelength conversion layer 30 having a higher proportion of the content of the first phosphor particles that generate blue light relative to that of the first wavelength conversion layer 30 is used.

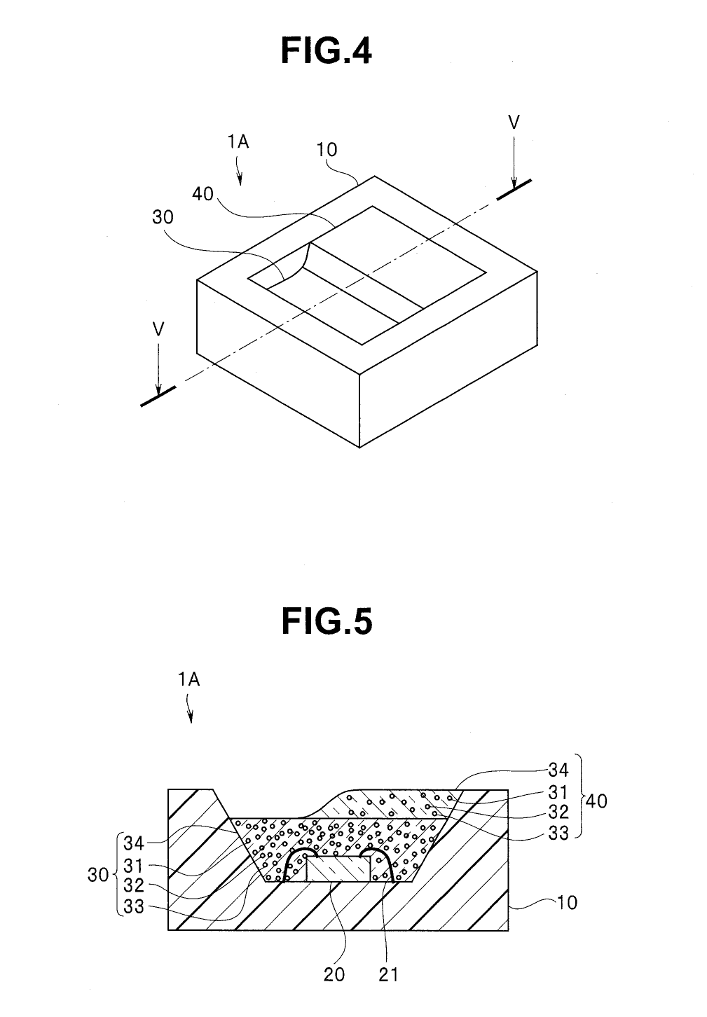

Also, if it is determined that as a result of the measurement in step S13 that the in-plane variation largely exceeds the relevant predetermined specification, as in a light-emitting device 1A, which is illustrated in FIGS. 4 and 5, a second wavelength conversion layer 40 may be placed on a part of a first wavelength conversion layer 30, or the second wavelength conversion layer 40 may have a thickness that differs within the plane. Also, a stepped portion may be formed at inner walls of the recess portion as an indication of the thickness of the second wavelength conversion layer 40.

In other words, in a light-emitting device according to an embodiment, it is only necessary that a second wavelength conversion layer 40 is placed on at least a part of a first wavelength conversion layer 30. For the partial placement of the second wavelength conversion layer 40, a dispenser method or an inkjet method may be used, or the second wavelength conversion layer 40 may partially be removed after placement of the second wavelength conversion layer 40 on the entire surface of the first wavelength conversion layer 30. Also, any of the aforementioned methods may be used for making the thickness of the second wavelength conversion layer 40 vary within the plane.

Also, a plurality of second wavelength conversion layers 40 having different compositions may respectively be placed at different positions in the first wavelength conversion layer 30. In other words, it is possible that a second wavelength conversion layer having a high third phosphor particle content is placed on a region of the first wavelength conversion layer 30 in which the amount of red light is small, and a second wavelength conversion layer with a high first phosphor particle content is placed on a region of the first wavelength conversion layer 30 in which the amount of blue light is small.

In other words, the composition (the amounts of phosphor particles contained and the proportions of contents of phosphor particles), the placement position and the thickness of the second wavelength conversion layer 40 can be changed according to the result of measurement of the light generated by the first wavelength conversion layer 30.

With a conventional light-emitting device, in order to provide light meeting predetermined specifications, three types of phosphors are mixed with a transparent resin at a predetermined ratio. However, for example, what is called color unevenness sometimes occurs due to the effect of, e.g., the dispersibilities of the phosphors in the transparent resin.

In particular, in a light-emitting device in an illumination apparatus used in a medical endoscope, subtle color shades, i.e., differences in tint largely affect, e.g., diagnosis and oversight of a diseased tissue. Thus, there is a need for a light-emitting device that generates light having more evenness in intensity and color.

A light-emitting device according to an embodiment generates light having evenness in intensity and color because the light is corrected by a second wavelength conversion layer 40. Thus, a light-emitting device according to an embodiment can be preferably used particularly in an illumination apparatus of a medical endoscope.

### Second Embodiment

Next, a light-emitting device 1B according to a second embodiment will be described. The light-emitting device 1B is similar to the light-emitting device 1 according to the first embodiment, and thus, components that are the same as those of the light-emitting device 1 are provided with reference numerals that are the same as those of the light-emitting device 1 and a description thereof will be omitted.

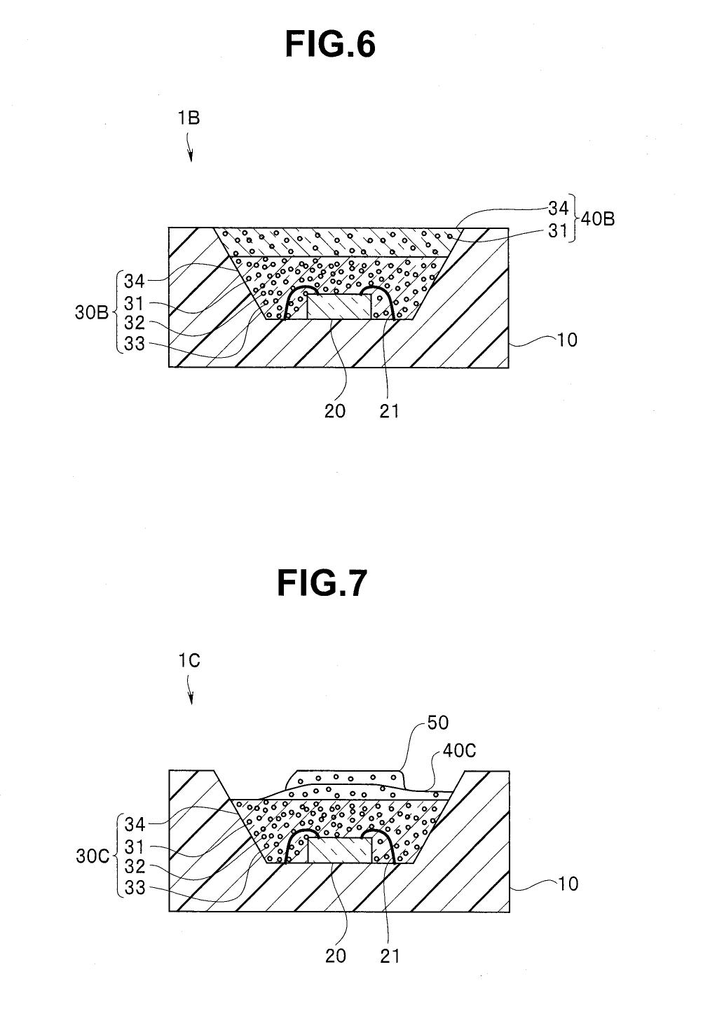

A second wavelength conversion layer 40B of the light-emitting device 1B illustrated in FIG. 6 contains first phosphor particles 31 as phosphor particles but contains neither second phosphor particles 32 nor third phosphor particles 33.

Then, the first wavelength conversion layer 30B is designed to generate not light meeting final specifications of the light-emitting device 1B, but light having a small amount of blue light. In other words, blue light generated by the first phosphor particles 31 is absorbed by the second phosphor particles 32 and the third phosphor particles 33 and thereby converted to green light and red light, which have longer wavelengths. Thus, blue light generated by the first wavelength conversion layer 30B is reduced if the second phosphor particles 32 and the third phosphor particles 33 are contained in the second wavelength conversion layer 40B, which may make proper correction uneasy. Also, it is not easy to enhance only the intensity of blue light in three color-mixed light.

However, in the light-emitting device 1B, the second wavelength conversion layer 40B contains neither the second phosphor particles 32 nor the third phosphor particles 33, and thus, the intensity of the blue light can easily be enhanced and correction can easily be made.

The light-emitting device 1B has effects similar to those of the light-emitting device 1, and furthermore, can easily be manufactured. Furthermore, the light-emitting device 1B has an enhanced light emission intensity because of the low rate of blue light emitted by a lower layer being absorbed by phosphor particles in an upper layer. Furthermore, the second wavelength conversion layer 40B contains only one type of phosphor particles, and thus, even dispersion of the phosphor particles in a transparent resin can easily be conducted.

Also, in some cases, the second wavelength conversion layer 40B may contain at least either of the second phosphor particles 32 and the third phosphor particles 33 if the content thereof is lower than that of the first wavelength conversion layer 30B.

### Third Embodiment

Next, a light-emitting device 1C according to a third embodiment will be described. The light-emitting device 1C is similar to the light-emitting devices 1 to 1B, and thus, components that are the same as those of the light-emitting devices 1 to 1B are provided with reference numerals that are the same as those of the light-emitting devices 1 to 1B and a description thereof will be omitted.

As illustrated in FIG. 7, the light-emitting device 1C according to the third embodiment includes a third wavelength conversion layer 50C in addition to a first wavelength conversion layer 30C and a second wavelength conversion layer 40C. The third wavelength conversion layer 50C is a second correction layer placed based on a result of measurement of light generated by the second wavelength conversion layer 40C.

In other words, it is only necessary that a light-emitting device according to an embodiment include at least one correction layer. Then, an upper layer contains an amount of phosphor particles that is smaller than that of a lower layer immediately below the upper layer. Also, it is preferable that a correction layer, which is an uppermost layer, contain only phosphor particles that generate blue light.

Also, a plurality of light-emitting elements may be mounted in a light-emitting device. The plurality of light-emitting elements may have a same size or different sizes, and may emit light in different colors.

Furthermore, a reflector having a reflection portion function may be formed at inner walls of a recess portion of the package 10. For the reflector, a reflective film may be formed by forming a reflective film having a high reflectivity and including, e.g., aluminum (Al), gold (Au) or nickel (Ni) by means of a vapor deposition method or a plating method, or a highly-reflective finish may be provided on the inner walls. Furthermore, a reflective film may be formed or a highly-reflective finish may be performed also on a bottom surface of the recess portion.

Having described the preferred embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A light-emitting device comprising:
a light-emitting element that generates ultraviolet light;
a first wavelength conversion layer placed on the light-emitting element, the first wavelength conversion layer including a plurality of types of phosphor particles dispersed in a transparent resin, each of the plurality of types of phosphor particles converting the ultraviolet light into light having a longer wavelength; and
a second wavelength conversion layer placed on at least a part of the first wavelength conversion layer, the second wavelength conversion layer including at least any of the plurality types of phosphor particles dispersed in the transparent resin.

2. The light-emitting device according to claim 1, wherein the second wavelength conversion layer is a correction layer that corrects light generated by the first wavelength conversion layer to light meeting a predetermined specification.

3. The light-emitting device according to claim 2, wherein a phosphor particle content in the second wavelength conversion layer is smaller than a phosphor particle content in the first wavelength conversion layer.

4. The light-emitting device according to claim 3, wherein the plurality of types of phosphor particles are a first phosphor particle that converts the ultraviolet light to blue light, a second phosphor particle that converts the ultraviolet light to green light and a third phosphor particle that converts the ultraviolet light to red light.

5. The light-emitting device according to claim 4, wherein a content of the first phosphor particle in the second wavelength conversion layer is larger than a content of the first phosphor particle in the first wavelength conversion layer.

6. The light-emitting device according to claim 5, wherein the second wavelength conversion layer contains neither the second phosphor particle nor the third phosphor particle.

7. A light-emitting device manufacturing method comprising the steps of:
forming a first wavelength conversion layer on a light-emitting element that generates ultraviolet light, the first wavelength conversion layer including a plurality of types of phosphor particles dispersed in a transparent resin, each of the plurality of types of phosphor particles converting the ultraviolet light to light having a longer wavelength;
measuring light generated by the first wavelength conversion layer; and
depositing, based on a result of the measurement, a second wavelength conversion layer on at least part of the first wavelength conversion layer, the second wavelength conversion layer including at least any of the plurality of types of phosphor particles dispersed in the transparent resin, to correct light generated by the first wavelength conversion layer to light meeting a predetermined specification.

8. The light-emitting device manufacturing method according to claim 7, wherein a phosphor particle content in the second wavelength conversion layer is smaller than a phosphor particle content in the first wavelength conversion layer.

9. The light-emitting device manufacturing method according to claim 8, wherein the plurality of types of phosphor particles are a first phosphor particle that converts the ultraviolet light to blue light, a second phosphor particle that converts the ultraviolet light to green light and a third phosphor particle that converts the ultraviolet light to red light.

10. The light-emitting device manufacturing method according to claim 9, wherein a content of the first phosphor particle in the second wavelength conversion layer is larger than a content of the first phosphor particle in the first wavelength conversion layer.

11. The light-emitting device manufacturing method according to claim 10, wherein the second wavelength conversion layer contains neither the second phosphor particle nor the third phosphor particle.
